(19) United States
(12) Patent Application Publication
(10) Pub. No.: US 2015/0278150 A1
(43) Pub. Date: Oct. 1, 2015

(54) IN-VEHICLE TELEMATICS UPGRADES

(71) Applicant: FORD GLOBAL TECHNOLOGIES, LLC, DEARBORN, MI (US)

(72) Inventors: Louis Vincent Bellanca, West Bloomfield, MI (US); Nunzio DeCia, Northville, MI (US); Stephen Michael Cunningham, Ann Arbor, MI (US)

(73) Assignee: FORD GLOBAL TECHNOLOGIES, LLC, DEARBORN, MI (US)

(21) Appl. No.: 14/228,761

(22) Filed: Mar. 28, 2014

(51) Int. Cl. G06F 13/42; B60R 16/03; G06F 17/50; H04R 5/02; H03G 5/16; B60K 37/06; B60R 16/02

(52) U.S. Cl. CPC G06F 13/4221; B60K 37/06; B60R 16/03; B60R 16/0207; H04R 5/02; H03G 5/165; G06F 17/5009; B60K 2350/1056; B60K 2350/1008; H04R 2499/13

(57) ABSTRACT

A system may include in-vehicle telematics adapter including a telematics unit configured to implement telematics functions for use within a vehicle, and a vehicle bus emulator connected to a vehicle bus input of the telematics unit configured to provide a simulated vehicle bus to allow the telematics unit to function outside of integration with the vehicle. A method may include receiving, by a vehicle bus emulator having a simulated vehicle bus output connected to a vehicle bus input of a telematics unit, a control notification indicative of user input from a user interface control; and generating a human-machine interface (HMI) control event message specifying the user input to the user interface control via the simulated vehicle bus output.

### TECHNICAL FIELD

The disclosure generally relates to telematics systems, and more particularly to in-vehicle telematics upgrades.

### BACKGROUND

Vehicle telematics systems may support various features, such as voice command recognition, navigation, music playback, as some examples. However, many vehicles on the road today do not implement these features. In some cases, a vehicle may have been purchased without a modern technology package. In other cases the vehicle may have been manufactured before certain services were commonly available, or by a vehicle manufacturer that fails to offer such functionality.

### SUMMARY

In a first illustrative embodiment, a system includes an in-vehicle telematics adapter including a telematics unit configured to implement vehicle telematics functions, and a vehicle bus emulator having a simulated vehicle bus output connected to a telematics unit vehicle bus input, the vehicle bus emulator configured to provide simulated vehicle bus messages to the telematics unit to allow the telematics unit to perform the telematics functions, as if the telematics unit were vehicle-integrated, outside of integration with a vehicle.

In a second illustrative embodiment, a method includes receiving, by a vehicle bus emulator having a simulated vehicle bus output connected to a vehicle bus input of a telematics unit, a control notification indicative of user input from a user interface control; and generating a human-machine interface (HMI) control event message specifying the user input to the user interface control via the simulated vehicle bus output.

In a third illustrative embodiment, a non-transitory computer-readable medium including instructions configured to be executed by a processor of a vehicle bus emulator having a simulated vehicle bus output connected to a vehicle bus input of a telematics unit, to cause the vehicle bus emulator to receive a control notification indicative of user input from a user interface control; and generate a human-machine interface (HMI) control event message specifying the user input to the user interface control via the simulated vehicle bus output.

### BRIEF DESCRIPTION OF THE DRAWINGS

FIG. 1 is an exemplary block topology of a vehicle infotainment system implementing a user-interactive vehicle based computing system;

FIG. 2 illustrates an exemplary in-vehicle telematics unit adapter for use in adding telematics features to a vehicle;

FIG. 3 illustrates an exemplary installation of the in-vehicle telematics unit adapter into the vehicle;

FIG. 4 illustrates an exemplary data flow diagram of operation of the in-vehicle telematics adapter installed into the vehicle; and

FIG. 5 illustrates an exemplary process for use of the in-vehicle telematics adapter installed into the vehicle to support a telematics feature in a vehicle.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

An in-vehicle adapter may be designed to allow for the incorporation of telematics features into a vehicle that may not include integrated telematics functionality. The in-vehicle adapter may include a telematics unit implementing the telematics functions, and a vehicle bus emulator to allow the telematics unit to operate without being connected to the actual vehicle bus. The vehicle bus emulator may be configured to simulate functionality of the vehicle bus to allow the telematics module to operate, such as vehicle power on/off sequencing, user interface events such as button presses, and human-machine interface (HMI) screen and mode selection, as the adapter may not include a display screen. In an example, the vehicle bus emulator may simulate aspects of a controller area network (CAN) bus to which the telematics unit may have been designed to be connected. The in-vehicle adapter may further include a harness configured to power the telematics unit, provide audio output from the telematics unit into an audio system of the vehicle, and provide user input to the telematics unit and vehicle bus emulator, such as via control or audio inputs.

To incorporate the telematics features into the vehicle, a user may connect a power input of the in-vehicle adapter to an in-vehicle power source, connect audio output of the in-vehicle adapter to an audio input of the vehicle, and place one or more input controls into the vehicle cabin, such as an auxiliary button that when pressed may invoke telematics functionality and a microphone to capture audio input. Accordingly, by addition of the in-vehicle adapter into the vehicle cabin, a user of the vehicle may be able to take advantage of telematics features not originally available with the vehicle.

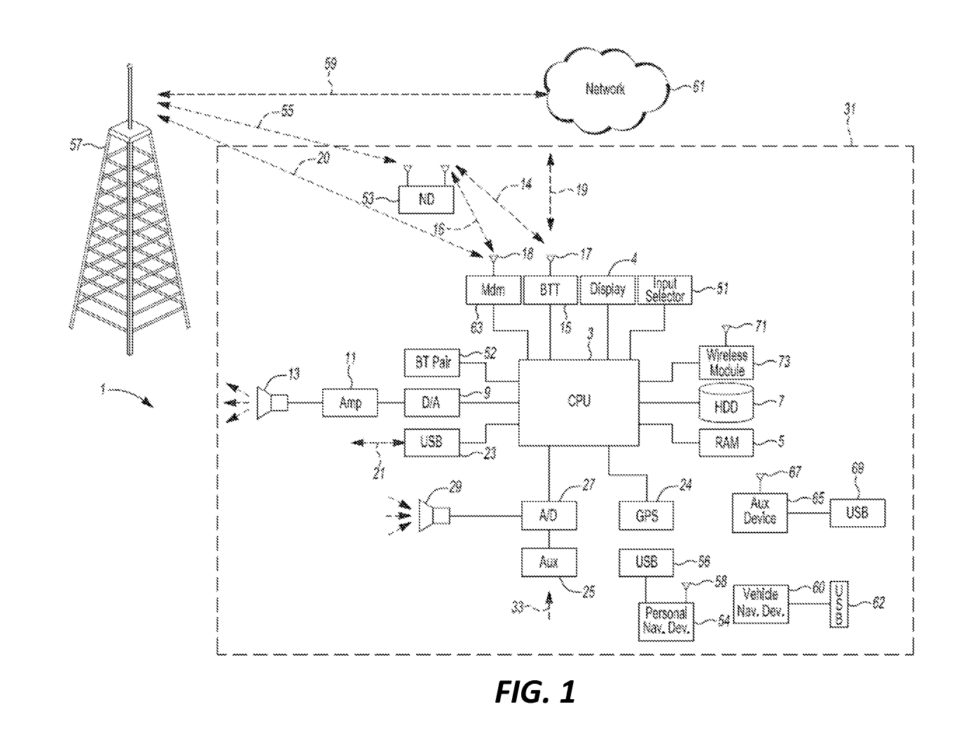

FIG. 1 illustrates an example block topology for a vehicle based computing system 1 (VCS) for a vehicle 31. An example of such a vehicle-based computing system 1 is the SYNC system manufactured by THE FORD MOTOR COMPANY. A vehicle enabled with a vehicle-based computing system may contain a visual front end interface 4 located in the vehicle. The user may also be able to interact with the interface if it is provided, for example, with a touch sensitive screen. In another illustrative embodiment, the interaction occurs through, button presses, spoken dialog system with automatic speech recognition and speech synthesis.

In the illustrative embodiment 1 shown in FIG. 1, a processor 3 controls at least some portion of the operation of the vehicle-based computing system. Provided within the vehicle, the processor allows onboard processing of commands and routines. Further, the processor is connected to both non-persistent 5 and persistent storage 7. In this illustrative embodiment, the non-persistent storage is random access memory (RAM) and the persistent storage is a hard disk drive (HDD) or flash memory. In general, persistent (non-transitory) memory can include all forms of memory that maintain data when a computer or other device is powered down. These include, but are not limited to, HDDs, CDs, DVDs, magnetic tapes, solid state drives, portable USB drives and any other suitable form of persistent memory.

The processor is also provided with a number of different inputs allowing the user to interface with the processor. In this illustrative embodiment, a microphone 29, an auxiliary input 25 (for input 33), a USB input 23, a GPS input 24, screen 4, which may be a touchscreen display, and a BLUETOOTH input 15 are all provided. An input selector 51 is also provided, to allow a user to swap between various inputs. Input to both the microphone and the auxiliary connector is converted from analog to digital by a converter 27 before being passed to the processor. Although not shown, numerous of the vehicle components and auxiliary components in communication with the VCS may use a vehicle network (such as, but not limited to, a CAN bus) to pass data to and from the VCS (or components thereof).

Outputs to the system can include, but are not limited to, a visual display 4 and a speaker 13 or stereo system output. The speaker is connected to an amplifier 11 and receives its signal from the processor 3 through a digital-to-analog converter 9. Output can also be made to a remote BLUETOOTH device such as PND 54 or a USB device such as vehicle navigation device 60 along the bi-directional data streams shown at 19 and 21 respectively.

In one illustrative embodiment, the system 1 uses the BLUETOOTH transceiver 15 to communicate 17 with a user's nomadic device 53 (e.g., cell phone, smart phone, PDA, or any other device having wireless remote network connectivity). The nomadic device can then be used to communicate 59 with a network 61 outside the vehicle 31 through, for example, communication 55 with a cellular tower 57. In some embodiments, tower 57 may be a WiFi access point.

Exemplary communication between the nomadic device and the BLUETOOTH transceiver is represented by signal 14.

Pairing a nomadic device 53 and the BLUETOOTH transceiver 15 can be instructed through a button 52 or similar input. Accordingly, the CPU is instructed that the onboard BLUETOOTH transceiver will be paired with a BLUETOOTH transceiver in a nomadic device.

Data may be communicated between CPU 3 and network 61 utilizing, for example, a data-plan, data over voice, or DTMF tones associated with nomadic device 53. Alternatively, it may be desirable to include an onboard modem 63 having antenna 18 in order to communicate 16 data between CPU 3 and network 61 over the voice band. The nomadic device 53 can then be used to communicate 59 with a network 61 outside the vehicle 31 through, for example, communication 55 with a cellular tower 57. In some embodiments, the modem 63 may establish communication 20 with the tower 57 for communicating with network 61. As a non-limiting example, modem 63 may be a USB cellular modem and communication 20 may be cellular communication.

In one illustrative embodiment, the processor is provided with an operating system including an API to communicate with modem application software. The modem application software may access an embedded module or firmware on the BLUETOOTH transceiver to complete wireless communication with a remote BLUETOOTH transceiver (such as that found in a nomadic device). Bluetooth is a subset of the IEEE 802 PAN (personal area network) protocols. IEEE 802 LAN (local area network) protocols include WiFi and have considerable cross-functionality with IEEE 802 PAN. Both are suitable for wireless communication within a vehicle. Another communication means that can be used in this realm is free-space optical communication (such as IrDA) and non-standardized consumer IR protocols.

In another embodiment, nomadic device 53 includes a modem for voice band or broadband data communication. In the data-over-voice embodiment, a technique known as frequency division multiplexing may be implemented when the owner of the nomadic device can talk over the device while data is being transferred. At other times, when the owner is not using the device, the data transfer can use the whole bandwidth (300 Hz to 3.4 kHz in one example). While frequency division multiplexing may be common for analog cellular communication between the vehicle and the internet, and is still used, it has been largely replaced by hybrids of Code Domain Multiple Access (CDMA), Time Domain Multiple Access (TDMA), Space-Domain Multiple Access (SDMA) for digital cellular communication. These are all ITU IMT-2000 (3G) compliant standards and offer data rates up to 2 mbs for stationary or walking users and 385 kbs for users in a moving vehicle. 3G standards are now being replaced by IMT-Advanced (4G) which offers 100 mbs for users in a vehicle and 1 gbs for stationary users. If the user has a data-plan associated with the nomadic device, it is possible that the data-plan allows for broad-band transmission and the system could use a much wider bandwidth (speeding up data transfer). In still another embodiment, nomadic device 53 is replaced with a cellular communication device (not shown) that is installed to vehicle 31. In yet another embodiment, the ND 53 may be a wireless local area network (LAN) device capable of communication over, for example (and without limitation), an 802.11g network (i.e., WiFi) or a WiMax network.

In one embodiment, incoming data can be passed through the nomadic device via a data-over-voice or data-plan, through the onboard BLUETOOTH transceiver and into the vehicle's internal processor 3. In the case of certain temporary data, for example, the data can be stored on the HDD or other storage media 7 until such time as the data is no longer needed.

Additional sources that may interface with the vehicle include a personal navigation device 54, having, for example, a USB connection 56 and/or an antenna 58, a vehicle navigation device 60 having a USB 62 or other connection, an onboard GPS device 24, or remote navigation system (not shown) having connectivity to network 61. USB is one of a class of serial networking protocols. IEEE 1394 (FireWire™ (Apple), i.LINK™ (Sony), and Lynx™ (Texas Instruments)), EIA (Electronics Industry Association) serial protocols, IEEE 1284 (Centronics Port), S/PDIF (Sony/Philips Digital Interconnect Format) and USB-IF (USB Implementers Forum) form the backbone of the device-device serial standards. Most of the protocols can be implemented for either electrical or optical communication.

Further, the CPU could be in communication with a variety of other auxiliary devices 65. These devices can be connected through a wireless 67 or wired 69 connection. Auxiliary device 65 may include, but are not limited to, personal media players, wireless health devices, portable computers, and the like.

Also, or alternatively, the CPU could be connected to a vehicle based wireless router 73, using for example a WiFi (IEEE 803.11) 71 transceiver. This could allow the CPU to connect to remote networks in range of the local router 73.

In addition to having exemplary processes executed by a vehicle computing system located in a vehicle, in certain embodiments, the exemplary processes may be executed by a computing system in communication with a vehicle computing system. Such a system may include, but is not limited to, a wireless device (e.g., and without limitation, a mobile phone) or a remote computing system (e.g., and without limitation, a server) connected through the wireless device. Collectively, such systems may be referred to as vehicle associated computing systems (VACS). In certain embodiments particular components of the VACS may perform particular portions of a process depending on the particular implementation of the system. By way of example and not limitation, if a process has a step of sending or receiving information with a paired wireless device, then it is likely that the wireless device is not performing the process, since the wireless device would not “send and receive” information with itself. One of ordinary skill in the art will understand when it is inappropriate to apply a particular VACS to a given solution. In all solutions, it is contemplated that at least the vehicle computing system (VCS) located within the vehicle itself is capable of performing the exemplary processes.

Many vehicles 31 on the road today do not have a CPU 3 as described in the context of FIG. 1. In some cases, a vehicle 31 may have been purchased without a modern technology package. In other cases the vehicle 31 may have been manufactured before certain services were commonly available, or by a vehicle manufacturer that fails to offer such functionality. Thus, in those vehicles 31, vehicle 31 telematics features such as directions and hands-free voice operation may be unavailable.

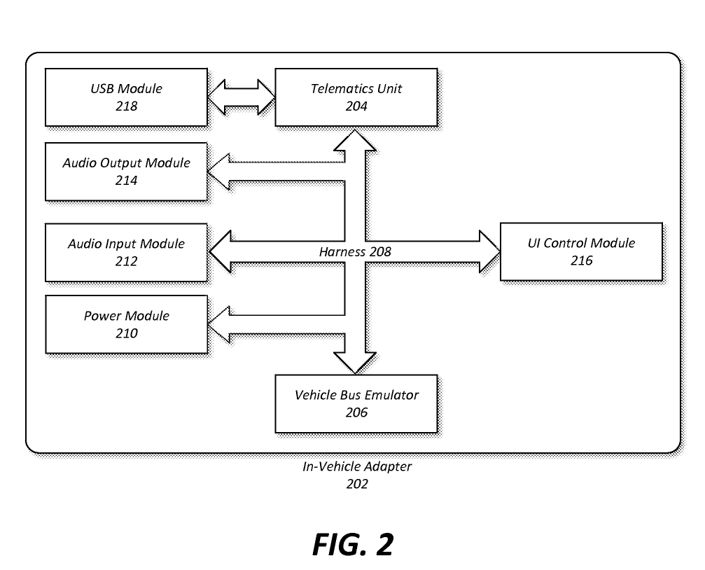

FIG. 2 illustrates an exemplary in-vehicle telematics unit adapter 202 for use in adding telematics features to a vehicle 31. As illustrated, the in-vehicle adapter 202 includes a telematics unit 204, a vehicle bus emulator 206, a harness 208, a power module 210, an audio input module 212, an audio output module 214, a user interface module 216, and a USB module 218. The vehicle bus emulator 206 may be configured to simulate signaling seen by the telematics unit 204 on the vehicle bus, to allow the telematics unit 204 to function outside of integration with the vehicle 31. The harness 208 may be configured to supply power from the power module 210 the telematics unit 204 and vehicle bus emulator 206, as well as to interconnect the telematics unit 204, vehicle bus emulator 206, audio input module 212, audio output module 214, and user interface control module 216. In some cases, the telematics unit 204 may be connected to a USB module 218 to expose USB functionality via the in-vehicle adapter 202. It should be noted that the modularization of the adapter 202 is merely exemplary, and more, fewer and/or differently partitioned adapter 202 modules may be used.

More specifically, the telematics unit 204 may be configured to implement telematics functions for use within the vehicle 31. These functions may include, as some examples, voice command recognition, navigation, and music or other media playback. As one possibility, the telematics unit 204 may be implemented as a processor typically integrated into a vehicle 31, such as in-vehicle integrated CPU 3 of FIG. 1 used to implement SYNC.

The vehicle bus emulator 206 may be configured to provide a simulated vehicle bus to allow the telematics unit 204 to function outside of integration with the vehicle 31. In an example, the vehicle bus emulator 206 may emulate a vehicle 31 CAN bus to which the telematics unit 204 expects to be connected. The vehicle bus emulator 206 may include simulated vehicle bus outputs, which may be wired to vehicle bus inputs of the telematics unit 204 in place of wiring into the actual vehicle bus. The vehicle bus emulator 206 may be further configured to place messages on the simulated vehicle bus to be detected by the telematics unit 204, causing the telematics unit 204 to be controlled by the vehicle bus emulator 206, rather than by vehicle 31 messages placed on the actual vehicle bus.

To emulate the specific messages to be placed on the simulated vehicle bus, the vehicle bus emulator may include an application or firmware program stored on a memory of the telematics unit adapter 202 (e.g., as software, firmware, etc.), such that when the program is executed by one or more processors of the vehicle bus emulator 206, the vehicle bus emulator 206 may be configured to perform various operations to emulate the environment in which the telematics unit 204 expects to operate.

For example, the vehicle bus emulator 206 may be configured to emulate power signaling that would be expected by the telematics unit 204, such as key-on signaling to activate the telematics unit 204 and key-off signaling to deactivate the telematics unit 204. As another example, as the in-vehicle adapter 202 may not include a display screen, the vehicle bus emulator 206 may be configured to emulate user interaction with the HMI or user interface of the telematics unit 204, to navigate the telematics unit 204 to user interface screen or menu in which options for various features of the telematics unit 204 are available. As yet a further example, the vehicle bus emulator 206 may be configured to emulate user interface user input events (such as button press events) that the telematics unit 204 may be configured to recognize on the vehicle bus to trigger telematics unit 204 functionality.

The harness 208 may be configured to facilitate the interconnection of the components of the adapter 202 with the vehicle 31. For example, the harness 208 may be configured to receive power from a power module 210 connected to the vehicle 31, and supply the received power to the various components of the adapter 202 (e.g., to the telematics unit 204, to the vehicle bus emulator 206, etc.) The power module 210, in turn, may be connected to a power source of the vehicle 31 external to the adapter 202, such as to a 12 Volt power port of the vehicle 31 or through hardwiring to the vehicle 31 electrical system. The power module 210 may include additional power related functionality, such as fusing of the received power or power conditioning to protect the adapter 202 from transients or other vehicle power-related issues.

When integrated directly into a vehicle 31, the audio input of the telematics unit 204 may be wired, for example, to the microphone 29. To emulate that functionality in the adapter 202, the harness 208 may be further configured to connect the audio input module 212 to an audio input of the telematics unit 204. In some cases, the audio input module 212 may include a microphone or other audio capture device integrated into the apparatus 202 and connected to the telematics unit 204. Additionally or alternately, the audio input device 212 may include an audio capture device external to the apparatus 202, such as a hardwired or plugged-in microphone. In some cases, the audio input device 212 may include an internal audio capture device integrated into the apparatus 202 and also an input for an external audio capture device that may be connected to the apparatus 202, as well as switching functionality to allow for the selection between the audio inputs.

When integrated directly into a vehicle 31, the audio outputs of the telematics unit 204 may be internally wired, for example, to the speakers 13 or stereo system output of the vehicle 31. To emulate that functionality in the adapter 202, the harness 208 may be further configured to connect the audio output module 214 to the one or more audio outputs of the telematics unit 204. In some cases, the audio outputs of the telematics unit 204 may be of a low level or may be susceptible to loading, so the audio output module 214 may further include an audio buffer amplifier to isolate the telematics unit 204 and adjust the audio output level. It should be noted that some telematics units 204 may utilize multiple audio outputs, such as a monaural audio output for synthesized voice and chime output and a stereo audio output for music output. In such units 204, the audio output module 214 may include separate amplifiers for each of the multiple audio outputs (e.g., a first amplifier for the mono output and another set of amplifiers for the stereo outputs), which may be adjustable by a user to allow the user to separately configure the levels of the outputs in a mix to be output. Additionally or alternately, the audio output module 214 may perform equalization on the various outputs that may vary by telematics unit 204 output.

The harness 208 may also be configured to connect the user interface control module 216 to the vehicle bus emulator 206. The user interface control module 216 may be configured to receive input from one or more user interface elements in communication with the user interface control module 216, and forward the output to the vehicle bus emulator 206 via the harness 208. Accordingly, the user interface control module 216 may allow the vehicle bus emulator 206 to receive user interface input and therefore emulate vehicle bus HMI events to be detected by the telematics unit 204. In an example, a button control wired to the user interface control module 216 may be connected to the apparatus 202, such that when the button is pressed, the user interface control module 216 may request that the vehicle bus emulator 206 emulate a message to invoke push-to-talk functionality of the telematics unit 204.

In some cases, the in-vehicle telematics unit adapter 202 may provide for other inputs as well. As one example, for telematics units 204 that support playback of media content from USB flash drives or portable music players, the in-vehicle telematics unit adapter 202 may include a USB module 218 exposing a USB connection to the telematics unit 204. This connection may accordingly to allow for user connection of a USB flash drive or portable music player to the telematics unit 204. As another example, for telematics units 204 that support a line input, the in-vehicle telematics unit adapter 202 may expose a line input jack to the telematics unit 204 (e.g., via an additional input to the audio input module 212) to facilitate the wiring in of an external audio source. By exposing the line input jack, the in-vehicle telematics unit adapter 202 may be able to preserve the line-in feature of the vehicle 31 into which the in-vehicle adapter 202 may be connected.

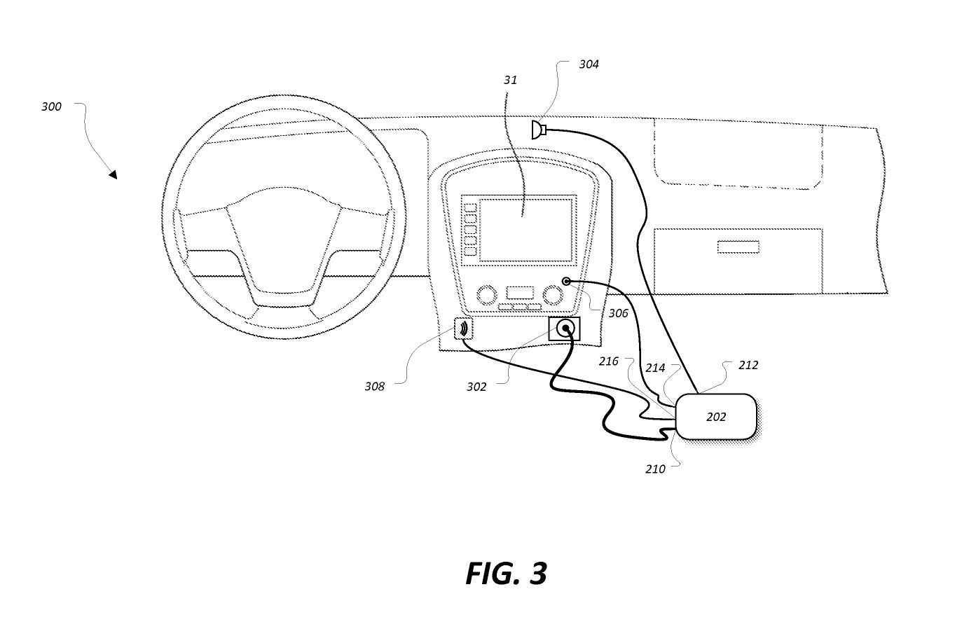

FIG. 3 illustrates an exemplary installation 300 of the in-vehicle telematics unit adapter 202 into the vehicle 31. As illustrated, the power module 210 of the adapter 202 may be connected to a power outlet 302 of the vehicle 31, such as to a 12 Volt accessory or cigarette lighter socket.

The audio input module 212 of the adapter 202 may be connected to an external audio capture device 304 installed in the vehicle cabin, such as a microphone, to allow the adapter 202 to receive audio command input from the user. In some cases, the audio capture device 304 may be hardwired to the adapter 202. As another possibility, the audio capture device 304 may be plugged into a connector of the audio input module 212, such as via a ¼″ or ⅛″ audio jack, or an XLR balanced input jack.

The audio output module 214 of the adapter 202 may be connected to an audio input 306 of the vehicle 31 to allow the in-vehicle adapter 202 to provide its audio output through the vehicle 31 audio system. As one possibility, the audio output module 214 may be connected by the user to a line input to the vehicle 31 audio system, such as via a vehicle 31 exposed line-in audio jack. As another possibility, such as for vehicles 31 lacking an audio input, the audio output module 214 may be connected to a low-power radio transmitter (e.g., broadcasting onto an FM frequency, or as another possibility the audio output module 214 may include the radio transmitter), such that the vehicle 31 radio may be tuned to the FM frequency to receive the audio output from the adapter 202.

The user interface control module 216 of the adapter 202 may be connected to a user interface control 308 installed in the vehicle cabin. In an example, the user interface control 308 may include a push-to-talk button placed within the vehicle cabin within reach of a user who is the vehicle. Once connected to the adapter 202, the user may be able to press the user interface control 308 to utilize the telematics features provided by the adapter 202.

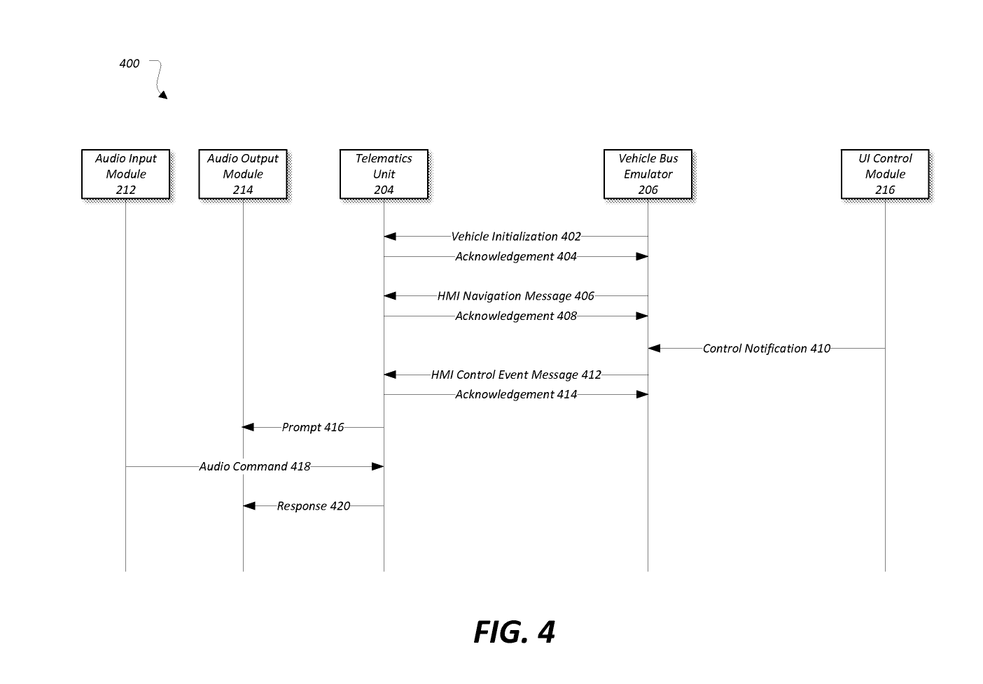

FIG. 4 illustrates an exemplary data flow 400 of operation of the in-vehicle telematics adapter 202 installed into the vehicle 31. The data flow 400 may begin with the vehicle bus emulator 206 simulating a vehicle initialization message 402 on the simulated vehicle bus between the vehicle bus emulator 206 and the adapter 202. This vehicle initialization message 402 may indicate a vehicle 31 key-on, which in turn may trigger activation of the telematics unit 204. Sending of the vehicle initialization message 402 may be triggered, for example, by power beginning to be supplied from the vehicle 31 to the adapter 202, or as another possibility by a user switching the adapter 202 into powered mode. The telematics unit 204 may further provide an acknowledgement message 404 to the vehicle initialization message 402 via the simulated bus, and the acknowledgement message 404 may be received by the vehicle bus emulator 206.

Responsive to or otherwise after receiving the acknowledgement message 404, the vehicle bus emulator 206 may be configured to simulate one or more HMI navigation messages 406 configured to navigate the user interface of the telematics unit 204 to a user interface screen in which the feature or features being made available by the adapter 202 are located in the telematics unit 204 menus. Typically, the telematics unit 204 may be able to utilize a head unit or other display device of the vehicle 31 to expose the current user interface screen to the user. However, when included in the adapter 202, the telematics unit 204 may lack display capability. In many cases, the telematics unit 204 may expose a modal user interface, in which the telematics unit 204 HMI will respond differently to user interface input depending on current state or screen of the HMI. As one example, user input of an address may have a different meaning when a user is operating an add contact HMI screen as opposed to operating a navigation HMI screen. Accordingly, the HMI navigation message 406 may be provided by the vehicle bus emulator 206 to the telematics unit 204 to navigate the telematics unit 204 to the appropriate user interface screen to receive command input. The telematics unit 204 may further provide an HMI acknowledgement message 408 responsive to the HMI navigation message 406 via the simulated bus indicating whether the HMI navigation was successfully performed.

The HMI acknowledgement messages 408 may be received by the vehicle bus emulator 206, and used to allow the vehicle bus emulator 206 to confirm that the telematics unit 204 was navigated to the proper user interface screen. In cases where multiple HMI navigation messages 406 are required to adjust the mode of the telematics unit 204, the vehicle bus emulator 206 may utilize the HMI acknowledgement messages 408 to be informed when the telematics unit 204 is ready to receive the next HMI navigation message 406. When the HMI mode or screen navigation is complete, the user interface of the telematics unit 204 may be ready to receive input from the user.

A user wishing to invoke a voice feature of the telematics unit 204 of the adapter 202 may express that desire by manipulating the user interface control 308 connected to the user interface control module 216 of the adapter 202. In an example, the user may press a push-to-talk button placed within the vehicle cabin and connected to the user interface control module 216. The user interface control module 216 may identify that the user interface control 308 provided input, and may provide a control notification 410 to an input of the vehicle bus emulator 206. The vehicle bus emulator 206 may accordingly generate a HMI control event message 412 according to the event specified by the control notification 410. Continuing with the push-to-talk example, the vehicle bus emulator 206 may generate a push-to-talk button HMI control event message upon receipt of a control notification 410 indicating that the user pressed the push-to-talk button connected to the user interface control module 216. Upon receipt of the indication of the HMI control event message 412, the telematics unit 204 may invoke the requested functionality, and may provide a HMI control event acknowledgement 414 to the vehicle bus emulator 206.

When invoking the requested functionality, the telematics unit 204 may provide a prompt 416 such as a chime or a voice prompt to indicate to the user that the function has been invoked. For instance, the telematics unit 204 may provide the prompt 416 to the audio output module 214 via the one or more audio outputs of the telematics unit 204. In an example, the prompt 416 may be provided through the monaural output of the telematics unit 204. The audio output module 214 may be connected to the audio input 306 of the vehicle 31 to allow the in-vehicle adapter 202 to provide the prompt 416 to the user via the vehicle 31 audio system.

The user may respond to the prompt 416 with voice or another type of audio command 418. The audio input module 212 may receive the audio command 418 via an audio capture device integrated with or connected to the audio input module 212, and may provide the audio command 418 to the telematics unit 204 via the connection of the audio input module 212 to the audio input to the telematics unit 204. (As another possibility, the user may respond to the prompt 416 by utilizing the same or another user interface control 308 connected to the user interface control module 216, such as by pressing the push-to-talk button again to discontinue the telematics unit 204 feature sequence.) The sequence may continue with the telematics unit 204 providing a response 420 to the audio command 418. The response 420 may include, for example, an indication of whether or not the audio command 418 was recognized by the telematics unit 204, a confirmation of the telematics unit 204, a response to a question posed by the audio command 418, and/or invocation of the requested feature, such as initiation of a phone call, turn-by-turn directions, or playback of one or more media files. Accordingly, these and other telematics functions may be provided for by way of the in-vehicle adapter 202 installed into to the vehicle 31.

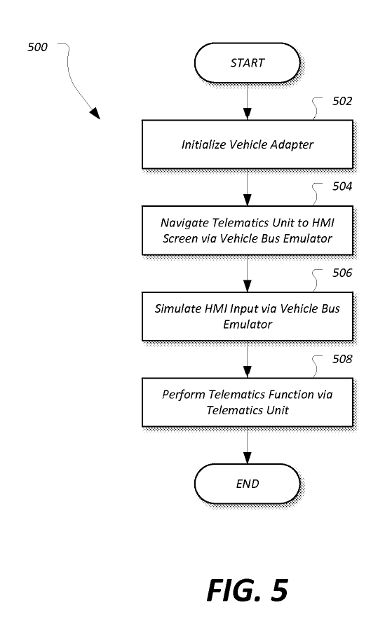

FIG. 5 illustrates an exemplary process 500 for use of the in-vehicle telematics adapter 202 installed into the vehicle 31 to support a telematics feature in a vehicle 31. The process 500 may be performed, for example, by the adapter 202 connected to the vehicle 31 as discussed above with respect to FIG. 3, the adapter 202 including a telematics unit 204 and a vehicle bus emulator 206, as discussed above with respect to FIG. 2.

At block 502, the adapter 202 initializes the telematics unit 204. For example, the vehicle bus emulator 206 may emulate, via the simulated vehicle bus output connected to the vehicle bus input of the telematics unit 204, power signaling expected by the telematics unit 204 on the vehicle bus such as key-on signaling to activate the telematics unit 204. The activation of the telematics unit 204 may be initiated, for example, by power beginning to be supplied from the vehicle 31 to the adapter 202, or as another possibility by a user switching the adapter 202 into powered mode.

At block 504, the adapter 202 navigates the telematics unit 204 to an HMI screen. For example, the vehicle bus emulator 206 may emulate, via the simulated vehicle bus output connected to the vehicle bus input of the telematics unit 204, one or more HMI navigation messages 406 to navigate the telematics unit 204 to an appropriate user interface screen to receive command input.

At block 506, the adapter 202 simulates HMI user input. For example, responsive to user input to the user interface control 308 connected to the user interface control module 216 of the adapter 202, user interface control module 216 may identify that the user interface control 308 provided input, and may provide a control notification 410 to an input of the vehicle bus emulator 206. The vehicle bus emulator 206 may accordingly generate a HMI control event message 412 according to the event specified by the control notification 410.

At block 508, the adapter 202 performs telematics function. For example, the telematics unit 204 may provide a prompt 416 such as a chime or a voice prompt to indicate to the user that the function has been invoked. The user may respond to the prompt 416 with voice or another type of audio command 418, and the telematics unit 204 may invoke of the requested feature, such as initiation of a phone call, turn-by-turn directions, or playback of one or more media files. Accordingly, these and other telematics functions may be provided for by way of the in-vehicle adapter 202 installed into to the vehicle 31.

Thus, by addition of the in-vehicle adapter 202 into the vehicle 31 cabin, a user of the vehicle 31 may be able to take advantage of telematics features not originally available with the vehicle 31.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A system comprising:
an in-vehicle telematics adapter including
a telematics unit configured to implement vehicle telematics functions, and
a vehicle bus emulator having a simulated vehicle bus output connected to a telematics unit vehicle bus input, the vehicle bus emulator configured to provide simulated vehicle bus messages to the telematics unit to allow the telematics unit to perform the telematics functions, as if the telematics unit were vehicle-integrated, outside of integration with a vehicle.

2. The system of claim 1, wherein the in-vehicle telematics adapter further comprises a harness connected to a power module configured to receive power from the vehicle, and further configured to provide the power via harness connection to the telematics unit and to the vehicle bus emulator.

3. The system of claim 1, wherein the in-vehicle telematics adapter further comprises an audio output module connected to at least one audio output of the telematics unit and configured to provide a mix of the at least one audio output to an audio output of the adapter.

4. The system of claim 3, wherein the at least one audio output includes a monaural audio output for providing telematics unit prompts and a stereo audio output for providing media content, and wherein the audio output module is further configured to independently adjust a level of the monaural audio output and a level of the stereo audio output to provide a mix of the monaural audio output and the stereo audio output in the audio output of the adapter.

5. The system of claim 3, wherein the at least one audio output includes a first audio output and a second audio output, and wherein the audio output module is further configured to apply a first equalization to the first audio output and a second equalization, different from the first equalization, to the second audio output.

6. The system of claim 1, wherein the vehicle bus is a controller area network (CAN), and wherein the vehicle bus emulator is configured to simulate CAN messages provided to the telematics unit via the CAN bus.

7. The system of claim 1, wherein the vehicle bus emulator is further configured to emulate power signaling expected by the telematics unit on the vehicle bus, including at least one of key-on signaling to activate the telematics unit and key-off signaling to deactivate the telematics unit.

8. The system of claim 1, wherein the vehicle bus emulator is further configured to emulate user interaction with a human-machine interface (HMI) of the telematics unit by providing at least one vehicle bus HMI event via the simulated vehicle bus output.

9. The system of claim 1, wherein the vehicle bus emulator is further configured to emulate at least one human-machine interface (HMI) navigation event to navigate the telematics unit to a user interface menu in which a predetermined telematics feature is available to be requested by a user.

10. The system of claim 1, wherein the vehicle bus emulator is further configured to receive a control notification from a user interface control module indicative of user input from a user interface control, and generate a human-machine interface (HMI) control event message specifying the user input to the user interface control via the simulated vehicle bus output.

11. The system of claim 10, wherein the user interface control is a push-to-talk user interface button, and the human-machine interface (HMI) control event message specifies that the push-to-talk user interface button was pressed by the user.

12. The system of claim 1, wherein the in-vehicle telematics adapter further comprises a universal serial bus (USB) module including a USB port connected to a USB input to the telematics unit, supporting user connection of at least one of a USB flash drive or a portable music player to the telematics unit.

13. A method comprising:
receiving, by a vehicle bus emulator having a simulated vehicle bus output connected to a vehicle bus input of a telematics unit, a control notification indicative of user input from a user interface control; and
generating a human-machine interface (HMI) control event message specifying the user input to the user interface control via the simulated vehicle bus output.

14. The method of claim 13, further comprising:
emulating, by a vehicle bus emulator, power signaling expected by the telematics unit on the vehicle bus, including at least one of key-on signaling to activate the telematics unit and key-off signaling to deactivate the telematics unit.

15. The method of claim 13, further comprising:
emulating, by a vehicle bus emulator, at least one human-machine interface (HMI) navigation event to navigate the telematics unit to a user interface menu in which a telematics feature is available to be requested by a user.

16. The method of claim 13, further comprising:
receiving at least one audio output from the telematics unit; and
provide a mix of the at least one audio output to an audio output of an adapter including the vehicle bus emulator, telematics unit, and audio output.

17. The method of claim 13, further comprising:
receiving an audio input from an audio capture device; and
providing the audio input to an audio input of the telematics unit.

18. A non-transitory computer-readable medium including instructions configured to be executed by a processor of a vehicle bus emulator having a simulated vehicle bus output connected to a vehicle bus input of a telematics unit, to cause the vehicle bus emulator to:
receive a control notification indicative of user input from a user interface control; and
generate a human-machine interface (HMI) control event message specifying the user input to the user interface control via the simulated vehicle bus output.

19. The medium of claim 18, further including instructions configured to be executed by the processor to cause the vehicle bus emulator to emulate power signaling expected by the telematics unit on the vehicle bus, including at least one of key-on signaling to activate the telematics unit and key-off signaling to deactivate the telematics unit.

20. The computer-readable medium of claim 18, further including instructions configured to be executed by the processor to cause the vehicle bus emulator to emulate at least one human-machine interface (HMI) navigation event to navigate the telematics unit to a user interface menu in which a telematics feature is available to be requested by a user.
